(19) United States
(12) Patent Application Publication
(10) Pub. No.: US 2014/0251664 A1
(43) Pub. Date: Sep. 11, 2014

(54) CIRCUIT SUBSTRATE

(71) Applicant: NGK Insulators, Ltd., Nagoya-shi (JP)

(72) Inventors: Yukio AISAKA, Kasugai-Shi (JP); Hirofumi YAMAGUCHI, Komaki-Shi (JP); Shinsuke YANO, Nagoya-Shi (JP)

(73) Assignee: NGK Insulators, Ltd., Nagoya-shi (JP)

(21) Appl. No.: 14/219,412

(22) Filed: Mar. 19, 2014

Related U.S. Application Data
(63) Continuation of application No. PCT/JP2013/066037, filed on Jun. 11, 2013.

(30) Foreign Application Priority Data
Mar. 11, 2013 (JP) 2013-047580

(51) Int. Cl. H05K 1/03

(52) U.S. Cl. CPC H05K 1/0306
USPC 174/255

(57) ABSTRACT

In a ceramics substrate comprising a surface layer conductor having a sufficient thickness for a flow of a large current, wherein the conductor is buried in a surface region of the substrate, a crack caused by a temperature change of the substrate is effectively suppressed. In the ceramics substrate comprising the surface layer conductor having the sufficient thickness for the flow of the large current, wherein the conductor is buried in the surface region of the substrate, a shape of a cross section of a part of the surface layer conductor, the part being buried in a base, cut by a plane perpendicular to the surface is configured such that an end portion of the buried part at a side of the surface is wider than an end portion of the buried part at a side opposite to the surface.

### TECHNICAL FIELD

The present invention relates to a circuit substrate. Especially, the present invention relates to the circuit substrate which comprises a surface layer conductor having a sufficient thickness for a flow of a large current.

### BACKGROUND ART

Many of circuit elements (e.g., power semiconductor device, or the like), used for a large current circuit constituting a high-capacity (large-current) module such as a power module (e.g., inverter, or the like), generate a large amount of heat when they operate. Thus, there may be a case in which a temperature of such a module rises due to the heat generated by the operation of the circuit element. Accordingly, in a case in which a resin is adopted as a base material for the circuit substrate of the large current circuit constituting the module, a stress due to a difference in a coefficient of thermal expansion between a material of a wafer (e.g. silicon (Si), or the like) of the power semiconductor device and the base material (resin) of the large-current-circuit substrate acts on a junction portion between the power semiconductor device and the substrate when such a temperature rise occurs, resulting in an occurrence of a problem, such as a crack, and a breaking of wire (disconnection) in the power semiconductor device, the substrate, and the junction portion.

Accordingly, it is preferable to select a material having a higher heat (thermal) resistance, as the base material for the large-current-circuit substrate. In view of the above, a dielectric layer mainly including ceramics has been widely adopted as the base material for the large-current-circuit substrate. Such a circuit substrate (hereinafter, it may be simply referred to as a “ceramic substrate”) adopting the dielectric layer mainly including the ceramics as the base material can achieve a higher reliability as compared with the circuit substrate (hereinafter, it may be simply referred to as a “resin substrate”) adopting the resin as the base material, because the ceramics has a higher heat resistance and a smaller coefficient of thermal expansion as compared with the resin.

Meanwhile, it is assumed that a large current flows through the surface layer conductor (e.g., surface electrode, or the like) provided on a surface (or in a surface region) of the large-current-circuit substrate used in the above described high-capacity module, and the like. Accordingly, it is preferable that at least a portion through which the large current flows in the surface layer conductor have a sufficiently large sectional area or a sufficiently large thickness for the flow of that large current. This can decrease an entire resistance loss of the module including an electronic circuit using the large-current-circuit substrate.

The surface layer conductor having the sufficiently large sectional area or the sufficiently large thickness for the flow of the large current as described above can be formed, for example, by laminating sheets, each having a slit corresponding to (a shape of) the surface layer conductor, on the surface of the circuit substrate, and thereafter, filling a depressed portion formed by the slits with a conductive paste (e.g., refer to Patent Literature 1).

However, in a case in which the surface layer conductor having the sufficiently large thickness (e.g., 50 μm or more) for the larger current is buried in a surface region of the ceramics substrate, a large stress are generated due to a difference in dimension change behavior (hereinafter, the behavior may also be referred to as a “thermal contraction behavior”) between the base material of the substrate and the surface layer conductor, the difference being caused by their temperature change when the temperature of the substrate changes in, for example, a firing process for the substrate, a mounting process of a module including the substrate, an operation period of the module including the substrate after its completion, or the like, since the thickness of the surface layer conductor is large. As a result, there may be a case in which a crack occurs, for example, in the base of the substrate in the vicinity of the surface layer conductor. Such a crack may cause a problem of, for example, a deterioration of the reliability (high-humidity reliability) of the substrate in high humidity environments.

On the other hand, in a small-current-circuit substrate in which fine wires are required in contrast to the large-current-circuit substrate, it is proposed to form the surface layer conductor such that a cross-sectional shape of the conductor is an inverted trapezoid for the purpose of enhancing an adhesion strength between the conductor constituting the fired wire and the base of the substrate (e.g., refer to Patent Literature 2 and Patent Literature 3). However, those prior arts neither take account of the crack that may occur in the ceramics substrate on which the surface layer conductor having the sufficiently large thickness for the large current as described above is formed due to the temperature change as described above, nor are suitable for burying the surface layer conductor having such a large thickness into the ceramics substrate (especially, the Patent Literature 3 states that a transfer method which the Patent Literature 3 adopts cannot bury the surface layer conductor having a thickness of 50 μm or more into the ceramics substrate).

As described above, in this technical field, a new technology has been needed which can effectively suppress the occurrence of the cracks caused by the temperature change of the ceramics substrate having the surface (region) in which the surface layer conductor having the sufficient thickness for the flow of the large current is buried.

### CITATION LIST

### Patent Literature

### Patent Literature 1

Japanese Patent Application Laid-Open (kokai) No. Hei 05-63373

### Patent Literature 2

Japanese Patent Application Laid-Open (kokai) No. Sho 62-35693

### Patent Literature 3

Japanese Patent Application Laid-Open (kokai) No. 2001-015895

### SUMMARY OF THE INVENTION

### Technical Problem

As described above, in this technical field, the new technology has been sought, which can effectively suppress the occurrence of the cracks due to the temperature change of the ceramics substrate having the surface (region) in which the surface layer conductor having the sufficient thickness for the flow of the large current is buried.

The present invention is achieved to meet such a need. More specifically, one of the objects of the present invention is to effectively suppress the occurrence of the cracks due to the temperature change of the ceramics substrate having the surface region in which the surface layer conductor having the sufficient thickness for the flow of the large current is buried, in the ceramics substrate which is used as the substrate of the large current circuit constituting the high-capacity (large-current) module such as the power module or the like (e.g. inverter, or the like).

### Solution to Problem

The above object is achieved by a circuit substrate comprising:

a base including at least a single dielectric layer mainly comprising ceramics; and

at least a single surface layer conductor formed at a first principal surface which is one of two principal surfaces,

wherein,

a part of the surface layer conductor is exposed from the base at the first principal surface, and the rest part of the surface layer conductor is buried in the base;

at least a part of the surface layer conductor has a thickness of 60 μm or more in a direction perpendicular to the first principal surface;

a shape of a cross section of the part of the surface layer conductor, the part being buried in the base, cut by a particular plane perpendicular to the first principal surface, includes a side E1 which is a line of intersection of the cross section and the first principal surface, and a side E2 parallel to the side E1;

a length L1 of the side E1 is longer than a length L2 of the side E2; and

both ends of the side E2 are positioned between both ends of the side E1 in a projective plane parallel to the first principal surface.

### Effect of the Invention

According to the present invention, in the ceramics substrate including surface layer conductor having the sufficient thickness for the flow of the large current, the surface layer being buried in the surface region, the occurrence of the cracks due to the temperature change of the substrate can be effectively suppressed.

### BRIEF DESCRIPTION OF THE DRAWINGS

FIG. 1 is a schematic perspective view showing an appearance of a large current circuit substrate to which the present invention is applied.

FIG. 2 is a schematic sectional view of a surface layer conductor in a large current circuit substrate according to the prior art, cut by a plane perpendicular to a principal surface of the substrate.

FIG. 3 is a schematic sectional view of a surface layer conductor in a large current circuit substrate according to an embodiment of the present invention, cut by a plane perpendicular to a principal surface of the substrate.

FIG. 4 is a schematic sectional view of a surface layer conductor in a large current circuit substrate according to another embodiment of the present invention, cut by a plane perpendicular to a principal surface of the substrate.

FIG. 5 is a schematic sectional view of a surface layer conductor in a large current circuit substrate according to still another embodiment of the present invention, cut by a plane perpendicular to a principal surface of the substrate.

### DESCRIPTION OF THE EMBODIMENT

As described above, one of the objects of the present invention is to effectively suppress the occurrence of the cracks due to the temperature change of the ceramics substrate, in the ceramics substrate in which the surface layer conductor having the sufficient thickness for the flow of the large current is buried in the surface region, the ceramics substrate being used as the substrate of the large current circuit constituting the high-capacity (large-current) module such as the power module or the like (e.g. inverter).

The inventors have found through their extensive research for the purpose of achieving the above object that, in the ceramics substrate having the surface region in which the surface layer conductor having the sufficient thickness for the flow of the large current is buried, the cracks due to the temperature change of the substrate can be effectively suppressed by designing a cross sectional shape of a part of the surface layer conductor buried in the base, cut by a plane perpendicular to the surface of the substrate, such that an end portion of the buried part at a side of the surface is wider than an end portion of the buried part at a side opposite to the side of the surface, and has achieved the present invention based on this finding.

That is, a first embodiment of the present invention is a circuit substrate comprising:

a base formed of at least a single dielectric layer mainly including ceramics; and

at least a single surface layer conductor formed at a first principal surface which is one of two principal surfaces,

wherein,

a part of the surface layer conductor is exposed from the base at the first principal surface, and the rest part of the surface layer conductor is buried in the base;

at least a portion of the surface layer conductor has a thickness of 60 μm or more in a direction perpendicular to the first principal surface;

a shape of a cross section of the part of the surface layer conductor, the part being buried in the base, cut by a particular plane perpendicular to the first principal surface, includes a side E1 which is a line of intersection of the cross section and the first principal surface, and a side E2 parallel to the side E1;

a length L1 of the side E1 is longer than a length L2 of the side E2, and

both ends of the side E2 are positioned between both ends of the side E1 in a projective plane parallel to the first principal surface.

As described above, the circuit substrate according to the present embodiment comprises the base formed of at least the single dielectric layer mainly including ceramics; and at least the single surface layer conductor formed at the first principal surface which is one of the two principal surfaces. The base may be formed of a single dielectric layer, or be formed of two or more of dielectric layers. Further, the number of the surface layer conductor may be one, or two or more. Another surface layer conductor may be formed at a second principal surface which is the other principal surface of the two principal surfaces that the circuit substrate according to the present embodiment comprises. Furthermore, an inner layer conductor completely buried inside of the circuit substrate according to the present embodiment may be formed, and via conductors or the like to connect between those conductors may be formed.

In addition, as described above, the part of the surface layer conductor is exposed from the base at the first principal surface, and the rest part of the surface layer conductor is buried in the base, in the circuit substrate according to the present embodiment. The part of the surface layer conductor exposed from the base at the first principal surface may be exposed such that a (part of a) surface of the surface layer conductor and the first principal surface of the circuit substrate are in the same plane (i.e., they are “flush” with each other), or be exposed such that a partial portion of the surface layer conductor is projected from the first principal surface. In any event, the rest part of the surface layer conductor is buried in the base of the circuit substrate.

Further, as described above, in the circuit substrate according to the present embodiment, at least the portion of the surface layer conductor has a thickness of 60 μm or more in the direction perpendicular to the first principal surface. Thus, in the circuit substrate according to the present embodiment, a resistance loss can be smaller even when the large current flows through the surface layer conductor, so that an entire resistance loss of the module including this substrate can be made smaller. From this point of view, the thickness of at least the part of the surface layer conductor is preferably equal to or larger than 60 μm, and more preferably, equal to or larger than 80 μm. It should be noted that a portion of the conductor pattern, constituting the surface layer conductor, through which, for example, the large current is not designed to flow, does not necessarily need to have such a large thickness. In addition, when the circuit substrate according to the present embodiment comprises, for example, the another surface layer conductor, the inner layer conductor, the via conductor, or the like, as described above, it is preferable that a portion through which the large current is designed to flow within a conductor pattern constituting those conductors have such a large thickness, and in contrast, a portion through which the large current is not designed to flow within the conductor pattern does not necessarily need to have such a large thickness.

The circuit substrate can be manufactured according to any one of various well-known manufacturing methods in the arts. For example, the circuit substrate according to the present embodiment may be manufactured by a process comprising:

a forming step of forming a compact in which a material to become the surface layer conductor is provided at a surface, corresponding to the first principal surface, of a material to become the base; and

a simultaneous firing step of obtaining a fired body of the thus obtained compact by firing the compact, at a predetermined temperature, for a predetermined time period, and under a predetermined environment.

In addition, as described above, when the circuit substrate according to the present embodiment comprises, the another surface layer conductor formed at the second principal surface, the inner layer conductor completely buried inside of the circuit substrate, the via conductor electrically connecting between those conductors, or the like, the compact body in which those conductors are disposed at desired positions may be prepared by, for example, further providing a material to become the another surface layer conductor at a surface corresponding to the second principal surface of the material to become the base in the forming step, or by further providing a material to become the inner layer conductor or the via conductor between or inside of materials to become the base in the forming step.

Examples of techniques for performing the above described forming step may include, for example, a so-called “doctor blade method”, a so-called “gel casting method”, or the like. When the former “doctor blade method” is adopted, the above compact can be obtained by;

preparing a slurry formed by mixing, for example, a raw material powder including a dielectric (ceramics) and a sintering additive such as glass, an organic binder, a plasticizing agent, a solvent, and the like;

forming the thus prepared slurry using a doctor blade forming machine into a sheet-like compact (green sheet) having a desired thickness;

punching out the green sheet such that the green sheet has a desired size;

forming a via (through hole) as necessary;

forming electrodes (conductor patterns) by printing a paste including a conductive material such as silver on a surface of the green sheet and in the via according to, for example, a screen printing method; and

forming the above compact by precisely layering a plurality of the thus obtained green sheets, and thereafter, unifying the sheets through heating and pressurizing the sheets.

On the other hand, when the “gel casting method” is adopted, the above compact can be obtained by, for example;

providing a conductor pattern on a surface of a film-like or thin-plate-like protective base using a printing method such as a screen printing method;

pouring a slurry of a dielectric material (e.g., ceramics, or the like) into a portion where the conductor pattern was not provided; and

layering the required number of the sheets, each having the conductor pattern buried in the sheets, and obtained by solidifying the slurry, such that the conductor pattern becomes the surface electrode and/or the inner electrode.

As the above protective base, it is preferable that a resin film, such as a polyethylene terephthalate (PET) film, and a polyethylene naphthalate (PEN) film, is used. As the protective base, various film-like or thin-plate-like materials, such as a glass plate, a paper, and a metal, can be used, in addition to the resin film. Note, however, it is preferable that a flexible material be used for the protective base, from a view point of easiness for a peel-off operation.

Further, for example, a parting agent or the like may be applied onto a surface of the protective base for the purpose of enabling the sheet of the dielectric material to be easily peeled off from the protective base, or the like. For example, such a parting agent includes various chemicals known as a mold release agent in the relevant art. More specifically, as the parting agent, a known silicone series parting agent, a known fluorine series parting agent, or the like, may be used.

It is preferable that the conductor pattern be provided by forming a conductive paste including, as a main component, one or more of metals selecting, for example, from a group consisting of gold, silver, copper, and the like, and a thermo-setting resin precursor, onto the surface of the protective base using, for example, the screen printing method, or the like. As the thermo-setting resin precursor, a phenolic resin, a resol resin, an urethane resin, an epoxy resin, a melamine resin, or the like, may be used. Among those resins, the phenolic resin or the resol resin is more preferably used. After printing the conductive paste on the surface of the protective base, the conductor pattern is obtained by hardening the binder included in the conductive paste.

An example for the above described slurry containing the dielectric material is a slurry containing a resin, a ceramic powder, and a solvent. Here, the resin functions as a so-called “binder.” As such a resin, for example, a thermo-setting resin such as a phenolic resin, a resol resin, and a polyurethane resin; a polyurethane precursor containing polyol and polyisocyanate, or the like, can be used. Among those, the thermo-setting resin precursor containing polyol and polyisocyanate is more preferably used.

As the ceramic material used as the ceramic powder, either oxide ceramics or non-oxide ceramics may be used. For example, alumina (Al₂O₃), zirconia (ZrO₂), barium titanate (BaTiO₃), silicon nitride (Si₃N₄), silicon carbide (SiC), barium oxide (BaO), titanium oxide (TiO₂), silicon oxide (SiO₂), zinc oxide (ZnO₂), neodymium oxide (Nd₂O₃), or the like, may be used. Among these materials, one of them may be used solely, or two or more may be used in combination. Further, as long as the slurry can be prepared, a particle size of the ceramic material is not particularly limited.

The solvent described above is not particularly limited, as long as it can dissolve the resin serving as the binder (and dispersing agent, if used). An example of the solvent is a solvent having two or more of ester linkages in a molecular, such as polybasic acid ester (e.g., glutaric acid dimethyl, and the like), polyalcohol acid ester (e.g., triacetin (glyceryl triacetate), and the like.

Further, the slurry of the dielectric material may contain a dispersing agent, in addition to the resin, the ceramic powder, and the solvent, described above. Examples of the dispersing agents are polycarboxylic series copolymer, polycarboxylate, or the like. Adding such a dispersing agent can reduce a viscosity of the slurry, and provide the slurry with a high fluidity, before it is formed.

The thus obtained compact are fired (simultaneously fired) at the predetermined temperature, for the predetermined time period, and under the predetermined environment, in the following firing step, as described above, so that the circuit substrate according to the present embodiment is obtained as the fired compact. It should be noted that an example of a degreasing condition in the simultaneous firing step is a condition to keep the compact at a temperature between 700° C. and 900° C. for 5 to 40 hours. An example of a firing condition in the simultaneous firing step is a condition to keep the compact at a temperature between 900° C. and 1100° C. for 1 to 10 hours.

It should be noted that the surface layer conductor formed at the first principal surface of the circuit substrate according to the present embodiment may be arranged so as to be exposed at the first principal surface when the compact is formed in the above described forming step, for example. Alternatively, the surface layer conductor formed at the first principal surface of the circuit substrate according to the present embodiment may be arranged so as not to be exposed at the first principal surface when the compact is formed in the above described forming step, for example. In the latter case, the surface layer conductor may be made to be exposed by, for example, polishing a first-principal-surface-side surface of the compact, after the compact is formed in the above described forming step, and before the compact is fired in the following simultaneous firing step. Alternatively, after the compact formed in the above described forming step is fired in the following simultaneous firing step, the surface layer conductor may be made to be exposed by, for example, polishing a first-principal-surface-side surface of the thus obtained fired compact.

Meanwhile, as described above, in the circuit substrate according to the present embodiment, the part of the surface layer conductor is exposed from the base at the first principal surface, the rest part of the surface layer conductor is buried in the base, and at least a portion of the surface layer conductor has a thickness of 60 μm or more in the direction perpendicular to the first principal surface. Accordingly, in the circuit substrate according to the present embodiment, the resistance loss can be smaller even when the large current flows through the surface layer conductor, so that the entire resistance loss of the module including this substrate can be made smaller.

However, in a conventional ceramics substrate, a typical shape of a cross section of a part of the surface layer conductor, the part being buried in the base, cut by a particular plane perpendicular to the first principal surface, is rectangular, and therefore, as described above, in the thus configured conventional ceramics substrate, when the base and the surface layer conductor having the large thickness are simultaneously fired, a crack(s) may occur in the base of the substrate, for example, in the vicinity of the surface layer conductor, due to a difference in the thermal contraction behavior between the surface layer conductor and the base. In addition, as described above, not only in the firing process of the substrate, but also when a temperature of the substrate changes in a mounting process of the module including the substrate, an operation period of the module including the substrate after its completion, and the like, a crack(s) may occur in the base of the substrate, for example, in the vicinity of the surface layer conductor, due to the difference in the thermal contraction behavior between the surface layer conductor and the base.

In view of the above, as described above, in the circuit substrate according to the present embodiment, a shape of a cross section of the part of the surface layer conductor, the part being buried in the base, cut by the particular plane perpendicular to the first principal surface, includes the side E1 which is the line of intersection of the cross section and the first principal surface, and the side E2 parallel to the side E1; the length L1 of the side E1 is longer than the length L2 of the side E2; and the both ends of the side E2 are positioned between the both ends of the side E1 in the projective plane parallel to the first principal surface.

Specifically, as described above, in the case in which the part of the surface layer conductor is exposed such that the (part of the) surface of the surface layer conductor and the first principal surface of the circuit substrate are in the same plane (i.e., they are “flush” with each other), the side E1 corresponds to a surface of the surface layer conductor, the surface being exposed from the base at the first principal surface. On the other hand, in the case in which the partial portion of the surface layer conductor is projected from the first principal surface so as to be exposed, the side E1 corresponds to a cross section of the surface layer conductor, cut by the first principal surface.

In any case, the side E2 is one of sides defining a contour (outline) of the cross section of the part of the surface layer conductor, the part being buried in the base, cut by the particular plane perpendicular to the first principal surface, and the side E2 is parallel to the side E1. Generally, the side E2 is the most distant (farthermost) side from the first principal surface. In addition, the length of the side E1 is longer than the length of the side E2, and the both ends of the side E2 are positioned between the both ends of the side E1 in the projective plane parallel to the first principal surface. That is, a cross sectional shape of the part of the surface layer conductor, the part being buried in the base, cut by the particular plane perpendicular to the first principal surface, is a shape which becomes wider in the direction from the side E2 to the side E1, as a whole.

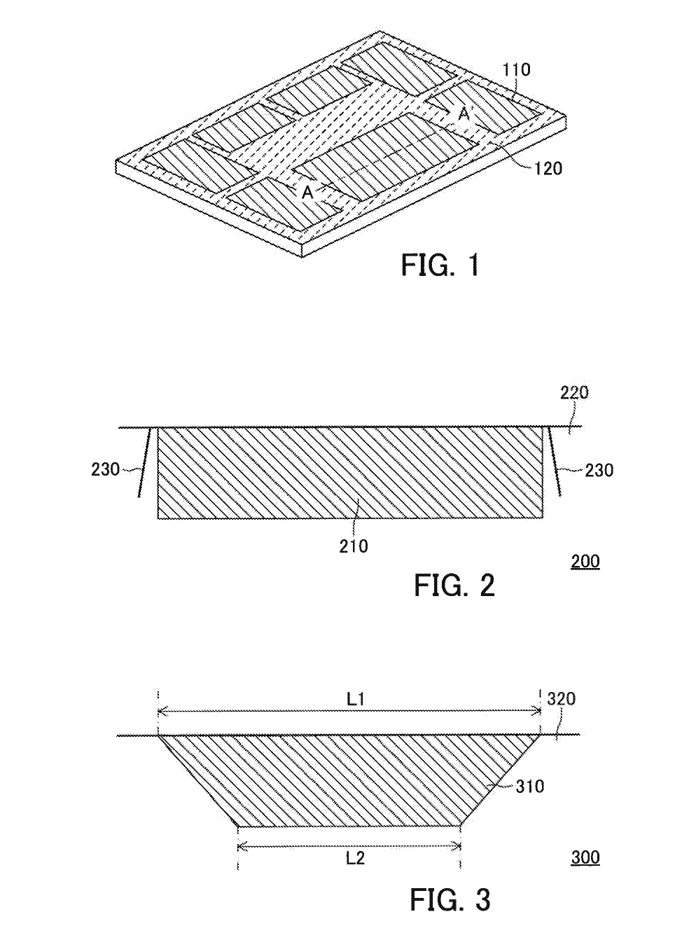

The above features will be described in more detail with reference to the attached drawings. Firstly, as described above, FIG. 1 is a schematic perspective view showing an appearance of the large current circuit substrate to which the present invention is applied. A plurality of conductor patterns 110 are formed, as the surface layer conductors, at the first principal surface (upper surface in FIG. 1) of the circuit substrate 100 shown in FIG. 1, so as to be exposed from a base 120 and in a plane flush with the first principal surface. In a case in which the large current circuit substrate having the above described structure is formed of the conventional ceramics substrate, a cross sectional shape of the surface layer conductor, cut by a plane, the plane passing through an alternate long and short dash line A-A′ shown in FIG. 1 and being perpendicular to the first principal surface, is generally rectangular, as shown by a shaded area 210 in FIG. 2.

As described above, FIG. 2 is a schematic sectional view of the surface layer conductor of the large current circuit substrate according to the prior art, cut by the particular plane perpendicular to the principal surface of the substrate. As shown in FIG. 2, in the thus configured large current circuit substrate according to the prior art, the crack(s) 230 is likely to occur in the base 220 of the substrate, for example, in the vicinity of the surface layer conductor 210, due to the difference in the thermal contraction behavior between the surface layer conductor and the base, not only in the firing process of the substrate 200, but also, when the temperature of the substrate changes, for example, in the mounting process of the module including the substrate, the operation period of the module including the substrate after its completion, and the like.

In contrast, as described above, in the circuit substrate according to the present embodiment, the shape of the cross section of the part of the surface layer conductor, the part being buried in the base, cut by the particular plane perpendicular to the first principal surface, includes: the side E1 which is the line of intersection of the cross section and the first principal surface; and the side E2 parallel to the side E1, wherein, the length of the side E1 is longer than the length of the side E2, and the both ends of the side E2 are positioned between the both ends of the side E1 in the projective plane parallel to the first principal surface. That is, as described above, in the circuit substrate according to the present embodiment, the shape of the cross section of the part of the surface layer conductor, the part being buried in the base, cut by the particular plane perpendicular to the first principal surface, is the shape which becomes wider in the direction from the side E2 to the side E1, as a whole. One of examples of such a cross sectional shape is a trapezoid (inverted trapezoid) as shown in FIG. 3.

As described above, FIG. 3 is a schematic sectional view of a surface layer conductor of a large current circuit substrate according to one of the embodiments of the present invention, cut by a plane perpendicular to a principal surface of the substrate. In the large current circuit substrate 300 according to the embodiment shown in FIG. 3, the cross section of the surface layer conductor 310 has a shape of an inverted trapezoid. That is, in the cross section of the surface layer conductor 310, an upper side (side E1) and a lower side (side E2) are parallel to each other, a length L1 of the upper side (side E1) is longer than a length L2 of the lower side (side E2), and both ends of the lower side (side E2) are positioned between both ends of the upper side (side E1) in a projective plane parallel to the first principal surface. In the large current circuit substrate 300 according to the embodiment shown in FIG. 3, in contrast to the conventional large current circuit substrate, since the cross section of the surface layer conductor 310 satisfies the above described conditions, the occurrence of the cracks in the base, for example, in the vicinity of the surface layer conductor 310 due to the difference in the thermal contraction behavior between the surface layer conductor 310 and the base 320, is suppressed, not only in the firing process of the substrate 300, but also, for example, when the temperature of the substrate 300 changes in the mounting process of the module including the substrate, the operation period of the module including the substrate after its completion, and the like.

A mechanism (reason) why the occurrence of the cracks in the base, for example, in the vicinity of the surface layer conductor when the temperature changes in the circuit substrate according to the present embodiment can be suppressed has not been figured out, however, it is inferred that a stress which is occurred due to the difference in the thermal contraction behavior between the surface layer conductor and the base is moderated and/or dispersed when the conditions that the shape of the cross section of the part of the surface layer conductor, the part being buried in the base, cut by the particular plane perpendicular to the first principal surface includes: the side E1 which is the line of intersection of the cross section and the first principal surface; and the side E2 parallel to the side E1, wherein the length of the side E1 is longer than the length of the side E2, and the both ends of the side E2 are positioned between the both ends of the side E1 in the projective plane parallel to the first principal surface are satisfied, resulting in suppressing the occurrence of the cracks.

The circuit substrate, as one of the concrete examples of the circuit substrate according to the present embodiment, has been described with reference to FIG. 3, the substrate having the surface layer conductor in which the shape of the cross section of the part of the surface layer conductor, the part being buried in the base, cut by the particular plane perpendicular to the first principal surface, which is the inverted trapezoid. However, the shape of the cross section of the part of the surface layer conductor, the part being buried in the base, in the circuit substrate according to the present embodiment is not particularly limited, as long as the conditions that the shape of the cross section of the part of the surface layer conductor, the part being buried in the base, cut by the particular plane perpendicular to the first principal surface, includes: the side E1 which is the line of intersection of the cross section and the first principal surface; and the side E2 parallel to the side E1, wherein the length of the side E1 is longer than the length of the side E2, and the both ends of the side E2 are positioned between the both ends of the side E1 in the projective plane parallel to the first principal surface, are satisfied.

That is, the shape of the cross section of the surface layer conductor in the circuit substrate according to the present embodiment can be appropriately selected from various shapes according to a requirement specification, or the like, of the circuit substrate to which the present invention is designed to be applied. For example, in the cross section of the part of the surface layer conductor in the circuit substrate according to the present embodiment, the part being buried in the base, cut by the particular plane perpendicular to the first principal surface, a line connecting between one end of the side E1 and one end of the side E2 may be, for example, a straight line (i.e., inverted trapezoid-like), step-like (i.e., inverted step-like), or a curve line.

In a case in which a partial portion of the surface layer conductor is projected from the first principal surface so as to be exposed, the portion (hereinafter, it may be referred to as a “projected portion”) projecting from the first principal surface may be formed so as to be united with a portion (hereinafter, it may be referred to as a “buried portion”) of the surface layer conductor, the portion being buried in the base, or alternatively, the projected portion and the buried portion are separately formed, and thereafter, are joined together. In the former case, for example, the projected portion may be formed by forming and firing it together with the buried portion. In the latter case, for example, the projected portion may be formed by forming the projected portion separately from the buried portion, separately firing the projected portion and the buried portion, and thereafter, joining the projected portion with the buried portion. Such a projected portion may be formed of the same material as the material of the buried portion, or be formed of a material different from the material of the buried portion (that is, the projected portion may be a lead frame, a metal foil, or the like).

Further, in the case in which the partial portion of the surface layer conductor is projected from the first principal surface so as to be exposed, in the projective plane parallel to the first principal surface, a size and a shape of the projected portion may be the same as a size and a shape of the buried portion, respectively, or alternatively, both of or either of a size and a shape of the projected portion may be different from both of or either of a size and a shape of the buried portion, respectively. In addition, the thickness of the projected portion in the direction perpendicular to the first principal surface may be appropriately determined according to, for example, a requirement specification etc. of the circuit substrate to which the present invention is designed to be applied.

Meanwhile, in the circuit substrate according to the present embodiment, the length of the side E1 is longer than the length L2 of the side E2. It is not preferable that a difference between the length L1 and the length L2 is excessively small, since the reduction effect of the cracks cannot be sufficiently obtained when the difference is too small. It is not preferable that the difference between the length L1 and the length L2 is excessively large, since an area of the cross section of the surface layer conductor becomes small when the difference is too large, and therefore, a resistance loss becomes large when the larger current flows through the surface layer conductor. In this manner, an appropriate range for the difference between the length L1 and the length L2 exists, and varies depending on the thickness of the surface layer conductor (in the direction perpendicular to the first principal surface). The preferable range for the difference between the length L1 and the length L2 in the circuit substrate according to the present embodiment is equal to or larger than 10 μm and equal to or smaller than 300 μm.

In view of the above, a second embodiment of the present invention is a circuit substrate including the features of the first embodiment of the present invention, wherein the difference between the length L1 and the length L2 is equal to or larger than 10 μm and equal to or smaller than 300 μm.

As described above, in the circuit substrate according to the present embodiment, the difference between the length L1 and the length L2 is 10 μm or more and 300 μm or less. The thus configured circuit substrate according to the present embodiment can sufficiently achieve the above described reduction effect of the cracks, while avoiding an increase of the resistance loss when the large current flows through the surface layer conductor.

As described above, the line connecting between one end of the side E1 and one end of the side E2 in the cross section of the part of the surface layer conductor, the part being buried in the base, cut by the particular plane perpendicular to the first principal surface, in the circuit substrate according to the present invention, may be, for example, the straight line (i.e., inverted trapezoid-like), step-like (i.e., inverted step-like), or the curve line.

In view of the above, a third embodiment of the present invention is a circuit substrate including either of the features of the first and second embodiments of the present invention, wherein the shape of the cross section is an inverted trapezoid having the side E1 as an upper base, and the side E2 as a lower base.

As described above, in the circuit substrate according to the present embodiment, the shape of the cross section is the inverted trapezoid having the sides E1 and E2 as the upper and lower bases, respectively (trapezoid having the upper base longer than the lower base). In this case as well, the shape of the cross section of the part of the surface layer conductor, the part being buried in the base, cut by the particular plane perpendicular to the first principal surface, becomes wider in the direction from the side E2 to the side E1, as described above. Accordingly, in the circuit substrate according to the present embodiment, the occurrence of the cracks in the base, for example, in the vicinity of the surface layer conductor, due to the difference in the thermal contraction behavior between the surface layer conductor and the base, is suppressed, not only in the firing process of the circuit substrate, but also when the temperature of the circuit substrate changes, for example, in the mounting process of the module including the circuit substrate, the operation period of the module including the circuit substrate after its completion, and the like.

It should be noted that a person having ordinary skill in the art can easily form the surface layer conductor having the cross sectional shape which is the above described inverted trapezoid in the circuit substrate according to the present embodiment, using, for example, the method for manufacturing the ceramic substrate as described above, or another method. Accordingly, specific processes will not be described in the present specification, however, the surface layer conductor having the cross sectional shape which is the inverted trapezoid in the circuit substrate according to the present embodiment can be formed by, for example, using a metal mask or the like, having an opening whose shape of a cross section cut by a plane perpendicular to a principal surface is formed to be a trapezoid when forming the conductor pattern which will become the surface layer conductor.

In addition, the circuit substrate, just as the circuit substrate according to the present embodiment, comprising the surface layer conductor having a shape of the cross section of the part of the surface layer conductor, the part being buried in the base, cut by the particular plane perpendicular to the first principal surface, which is the inverted trapezoid has already been described in detail with reference to FIG. 3, and thus, the description will not repeated.

As described above, the line connecting between one end of the side E1 and one end of the side E2 in the cross section of the part of the surface layer conductor in the circuit substrate according to the present invention, the part being buried in the base, cut by the particular plane perpendicular to the first principal surface may be, for example, the straight line (i.e., inverted trapezoid-like), step-like (i.e., inverted step-like), or the curve line.

In view of the above, a fourth embodiment of the present invention is a circuit substrate including either of the features of the first and second embodiments of the present invention, wherein,

the shape of the cross section is an inverted step-like shape obtained by layering a plurality of quadrangles including at least a quadrangle having the side E1 as one of four sides and a quadrangle having the side E2 as one of four sides; and

in a plane which includes a plane at which two of quadrangles next to each other among a plurality of the quadrangles constituting the inverted step-like shape contact with each other, both ends of a side of the quadrangle closer to said side E2 are positioned between both ends of a side of the quadrangle closer to said side E1.

As described above, in the circuit substrate according to the present embodiment, the shape of the cross section is the inverted step-like shape obtained by layering a plurality of quadrangles including at least a quadrangle having the side E1 as one of four sides, and a quadrangle having the side E2 as one of four sides; and in an plane which includes a plane at which two of the quadrangles next to each other among a plurality of the quadrangles constituting the inverted step-like shape contact with each other, both ends of the side of the quadrangle closer to the side E2 are positioned between both ends of the side of the quadrangle closer to the side E1. In the present specification, the inverted step-like shape means a shape obtained by vertically (top-bottom) inverting a step-like shape. In other words, in the circuit substrate according to the present embodiment, the shape of the cross section is a side connecting between an upper base and a lower base of an inverted trapezoid in which the upper base is longer than the lower base is replaced with a step-like line.

That is, in this case as well, as described above, the shape of the cross section of the part of the surface layer conductor, the part being buried in the base, cut by the particular plane perpendicular to the first principal surface, becomes wider in the direction from the side E2 to the side E1 as a whole. Accordingly, in the circuit substrate according to the present embodiment as well, the occurrence of the cracks in the base, for example, in the vicinity of the surface layer conductor, due to the difference in the thermal contraction behavior between the surface layer conductor and the base, is suppressed, not only in the firing process of the circuit substrate, but also, for example, when the temperature of the circuit substrate changes in the mounting process of the module including the circuit substrate, the operation period of the module including the circuit substrate after its completion, and the like.

It should be noted that a person having ordinary skill in the art can easily form the surface layer conductor having the cross sectional shape which is the above described inverted step-like shape in the circuit substrate according to the present embodiment, using, for example, the method for manufacturing the ceramic substrate as described above, or another method. Accordingly, specific processes will not be described in the present specification, however, the surface layer conductor having the cross sectional shape which is the inverted step-like shape in the circuit substrate according to the present embodiment can be formed by, for example, printing the conductor paste using the screen printing method such that a width of the conductor pattern to become the surface layer conductor becomes wider as it comes closer to the first principal surface when the conductor pattern to become the surface layer conductor is formed.

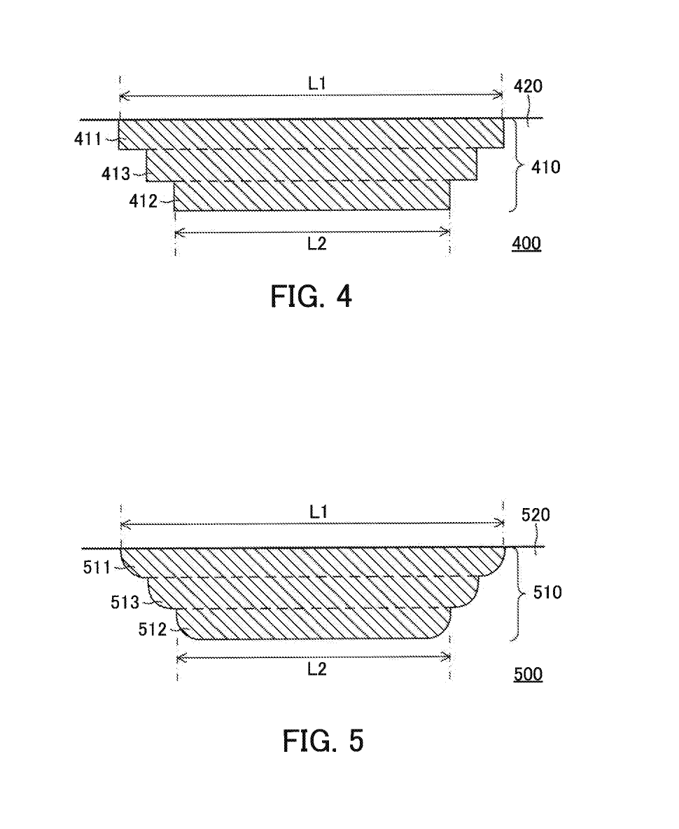

Hereinafter, the circuit substrate according to the present embodiment will be described in more detail, with reference to the attached drawing. As described above, FIG. 4 is a schematic sectional view of a surface layer conductor of a large current circuit substrate according to another embodiment of the present invention, cut by a plane perpendicular to a principal surface of the substrate. In the large current circuit substrate 400 according to the embodiment shown in FIG. 4, the cross section of the surface layer conductor 410 has an inverted step-like shape. More specifically, the shape of the cross section of the surface layer conductor 410 is the inverted step-like shape obtained by layering a quadrangle 411, a quadrangle 413, and a quadrangle 412, from the first principal surface side (i.e., from upper side in FIG. 4) in that order, wherein the quadrangle 411 has the side E1 as one of four sides, the quadrangle 412 has the side E2 as one of four sides, and the quadrangle 413 is disposed between the quadrangle 411 and the quadrangle 412. Note that a length of the side of the quadrangle 413, the side contacting the quadrangle 411 or the quadrangle 412 is shorter than the side E1, and longer than the side E2.

That is, in the large current circuit substrate 400 according to the embodiment shown in FIG. 4 as well, the shape of the cross section is the inverted step-like shape obtained by layering a plurality of the quadrangles including at least the quadrangle having the side E1 as one of the sides, and the quadrangle having the side E2 as one of the sides; and in an plane which includes a plane at which two of the quadrangles next to each other among a plurality of the quadrangles constituting the inverted step-like shape contact with each other, the both ends of the side of the quadrangle closer to the side E2 are positioned between the both ends of the side of the quadrangle closer to the side E1. In the large current circuit substrate 400 according to the embodiment shown in FIG. 4, in contrast to the conventional large current circuit substrate, but similarly to the circuit substrate according to the other embodiments described above of the present invention, since the cross section of the surface layer conductor 410 satisfies the above described conditions, the occurrence of the cracks in the base, for example, in the vicinity of the surface layer conductor 410 due to the difference in the thermal contraction behavior between the surface layer conductor 410 and the base 420, is suppressed, not only in the firing process of the substrate 400, but also, for example, when the temperature of the substrate 400 changes in the mounting process of the module including the substrate, the operation period of the module including the substrate after its completion, and the like.

Meanwhile, as described above, in the cross section of the part of the surface layer conductor, the part being buried in the base, cut by the particular plane perpendicular to the first principal surface, in the circuit substrate according to the present invention, the line connecting between one end of the side E1 and one end of the side E2 may be, for example, the straight line (i.e., inverted trapezoid-like), step-like (i.e., inverted step-like), or the curve line. In a case in which the surface layer conductor having the cross sectional shape which is the inverted step-like shape in the circuit substrate according to the present embodiment is formed by, for example, as described above, printing the conductor paste using the screen printing method such that the width of the conductor pattern which will be the surface layer conductor becomes wider as it comes closer to the first principal surface when the conductor pattern which will become the surface layer conductor is formed, a corner angle which corresponds to an angle of the corner of the step may be rounded (blurred) by, for example, adjusting a property (e.g., viscosity, or the like) of the conductor paste, instead of making the corner angle acute.

As described above, when the corner angle which corresponds to the angle of the corner of the step in the cross sectional shape of the step-like shape in the circuit substrate according to the present embodiment is made rounded (blurred), the number of corners is decreased, the corner being a portion at which the stress is likely to concentrate, the stress being caused due to the difference in the thermal contraction behavior between the surface layer conductor and the base when the temperature of the substrate changes. Accordingly, such a stress is moderated and/or dispersed, resulting in effectively suppressing the occurrence of the cracks due to the stress.

In view of the above, a fifth embodiment of the present invention is a circuit substrate including the features of the fourth embodiment of the present invention, wherein,

at least one of a plurality of corners corresponding to two corners closer to the side E2 among four corners which each of a plurality of the quadrangles forming the inverted step-like shape has is rounded.

As described above, in the circuit substrate according to the present embodiment, at least one of a plurality of the corners corresponding to the two corners closer to the side E2 among the four corners which each of a plurality of the quadrangles forming the inverted step-like shape has is rounded. In other words, in the circuit substrate according to the present embodiment, whereas the cross sectional shape of the part of the surface layer conductor, the part being buried in the base, cut by the particular plane perpendicular to the first principal surface, is approximately inverted step-like, at least the corner of one of a plurality of portions, each corresponding to the corner of the step, is not acute, but is rounded.

A curvature of the thus rounded corner is not particularly limited. Accordingly, the thus rounded corner may be a naturally rounded (blurred) corner in a process to form the surface layer conductor having the inverted step-like sectional shape as described above. That is, an intentional shaping process need not be carried out, so that the corner corresponding to the corner of the step does not become acute. Alternatively, the thus rounded corner may be obtained by, for example, performing the intentional shaping process, such as polishing and the like, after forming the surface layer conductor having the inverted step-like shape as described above.

In any case, in the circuit substrate according to the present embodiment as well, the shape of the cross section of the part of the surface layer conductor, the part being buried in the base, cut by the particular plane perpendicular to the first principal surface, becomes wider in the direction from the side E2 to the side E1, as a whole, as described above. Accordingly, in the circuit substrate according to the present embodiment as well, the occurrence of the cracks in the base, for example, in the vicinity of the surface layer conductor, due to the difference in the thermal contraction behavior between the surface layer conductor and the base, is suppressed, not only in the firing process of the circuit substrate, but also, when the temperature of the circuit substrate changes for example, in the mounting process of the module including the circuit substrate, the operation period of the module including the circuit substrate after its completion, and the like.

Hereinafter, the circuit substrate according to the present embodiment will be described in more detail, with reference to the attached drawing. As described above, FIG. 5 is a schematic sectional view of a surface layer conductor of a large current circuit substrate according to still another embodiment of the present invention, cut by a plane perpendicular to a principal surface of the substrate. In the large current circuit substrate 500 according to the embodiment shown in FIG. 5, whereas the cross sectional shape of surface layer conductor 510 is approximately inverted step-like, the corners of a plurality of portions, each corresponding to the corner of the step, is not acute, but is rounded (blurred). More specifically, the shape of the cross section of the surface layer conductor 510 is the approximately inverted step-like shape obtained by layering a figure 511, a figure 513, and a figure 512, from the first principal surface side (i.e., from upper side in FIG. 4) in that order, wherein the figure 511 is one in which two of the corners closer to the side E2 among four of the corners of the quadrangle having the side E1 as one of the sides are rounded, the figure 512 is one in which two of the corners closer to the side E2 among four of the corners of the quadrangle having the side E2 as one of the sides are rounded, and the figure 513 is disposed between the figure 511 and the figure 512 and has a shape similar to the figure 511 and the figure 512. Note that a length of the side of the figure 513, the side contacting the figure 511 or the figure 512, is shorter than the side E1, and longer than the side E2.

That is, the shape of the cross section of the surface layer conductor 510 in the large current circuit substrate 500 according to the embodiment shown in FIG. 5, is the inverted step-like shape which is basically similar to the shape of the cross section of the surface layer conductor 410 in the large current circuit substrate 400 according to the embodiment shown in FIG. 4, except that the corners of a plurality of portions, each corresponding to the corner of the step, are rounded. As a result, in the large current circuit substrate 500 according to the embodiment shown in FIG. 5 as well, in contrast to the conventional large current circuit substrate, but similarly to the circuit substrate according to the other embodiments described above of the present invention, the occurrence of the cracks in the base, for example, in the vicinity of the surface layer conductor 510, due to the difference in the thermal contraction behavior between the surface layer conductor 510 and the base 520 is suppressed, not only in the firing process of the substrate 500, but also, for example, when the temperature of the substrate changes in the mounting process of the module including the substrate, the operation period of the module including the substrate after its completion, and the like.

It should be noted that, as described above, the large current circuit substrates have been described, the substrates comprising the surface layer conductors, which have the three steps inverted step-like cross sectional shape and the three steps inverted step-like cross sectional shape whose corners are rounded in FIG. 4 and FIG. 5, respectively, however, as a matter of course, the number of steps in such a step-like cross sectional shape is not limited to three, but may be two, or four or more.

However, if a thickness (in the direction perpendicular to the first principal surface) per one step of such an inverted step-like cross sectional shape (that corresponds to a rise of the step) is excessively small, the number of the quadrangles constituting the inverted step-like cross sectional shape becomes excessively large, and therefore, for example, the process for forming the surface layer conductor becomes complicated and lengthy. Accordingly, the excessively small thickness of the step is not preferable. To the contrary, if the thickness per one step of such an inverted step-like cross sectional shape is excessively large, the number of the quadrangles constituting the inverted step-like cross sectional shape becomes small, and therefore, it becomes difficult to form the cross sectional shape of the surface layer conductor such that it becomes wider in the direction from the side E2 to the side E1 as a whole, resulting in weakening the crack reduction effect described above. Accordingly, the excessively large thickness of the step is not preferable.

Further, when a difference between sides on which two quadrangles next to each other contact with each other among a plurality of the quadrangles constituting the inverted step-like cross sectional shape (the difference corresponding to a depth of a tread of the step) is excessively small, it becomes difficult to form the cross sectional shape of the surface layer conductor such that it becomes wider in the direction from the side E2 to the side E1 as a whole, resulting in weakening the crack reduction effect described above. Accordingly, the excessively small difference between the sides is not preferable. To the contrary, if the difference between the sides on which two quadrangles next to each other contact with each other among a plurality of the quadrangles constituting the inverted step-like cross sectional shape is excessively large, an area of the cross section of the surface layer conductor becomes small, and therefore, the resistance loss becomes large when the large current flows through the surface layer conductor. Accordingly, the excessively large difference between the sides is not preferable.

In this manner, appropriate ranges exist, for the thickness per one step of the inverted step-like cross sectional shape, and for the difference between the sides on which two quadrangles next to each other contact with each other among a plurality of the quadrangles constituting the inverted step-like cross sectional shape. Through the inventors' extensive research, the inventors have found that the preferable range for the thickness per one step of the inverted step-like cross sectional shape is equal to or larger than 40 μm and equal to or smaller than 100 μm, and the preferable range for the difference between the sides on which two quadrangles net to each other contact with each other among a plurality of the quadrangles constituting the inverted step-like cross sectional shape is equal to or larger than 40 μm and equal to or smaller than 150 μm.

In view of the above, a sixth embodiment of the present invention is a circuit substrate including the features of either one of the fourth embodiment or the fifth embodiment, of the present invention, wherein,

a thickness of each of the quadrangles constituting the inverted step-like shape in a direction perpendicular to the first principal surface is equal to or larger than 40 μm and equal to or smaller than 100 μm; and

in an plane which includes a plane at which two of the quadrangles next to each other among a plurality of the quadrangles constituting the inverted step-like shape contact with each other, a difference between a length of a side of a quadrangle closer to the side E2 and a length of a side of a quadrangle closer to the side E1 is equal to or larger than 40 μm and equal to or smaller than 150 μm.

As described above, in the circuit substrate according to the present embodiment, the thickness of each of the quadrangles constituting the inverted step-like shape in the direction perpendicular to the first principal surface is 40 μm or more and 100 μm or less. In addition, in the circuit substrate according to the present embodiment, in the plane which includes the plane at which two of the quadrangles next to each other among a plurality of the quadrangles constituting the inverted step-like shape contact with each other, the difference between the length of the side of the quadrangle closer to the side E2 and the length of the side of the quadrangle closer to the side E1 is 40 μm or more and 150 μm or less. Accordingly, the circuit substrate according to the present embodiment can sufficiently achieve the above described reduction effect of the cracks, while avoiding an increase of the resistance loss when the large current flows through the surface layer conductor.

In the meantime, as was mentioned in the beginning of the present specification, the present invention relates to the circuit substrate which comprises the surface layer conductor having the sufficient thickness for the flow of the large current. That is, the circuit substrate according to the present invention is designed to be used as a substrate of a large current circuit which handles a large current. Accordingly, from a viewpoint of reducing the resistance loss of the circuit substrate according to the present invention, it is preferable to make an electric resistance of the conductor as small as possible of at least a portion through which a large current is designed to flow within the conductor pattern constituting the surface layer conductor which the present circuit substrate comprises (and, depending on the configuration, the another surface layer conductor, the inner conductor, the via conductor, or the like, as described above), so that a wiring resistance is lowered. As a main component for such a conductor pattern, gold, silver, copper, an alloy containing those metals, or the like, all of which are low resistance conductors, are preferably used.

In view of the above, a seventh embodiment of the present invention is a circuit substrate including the features of any one of the first to sixth embodiments of the present invention, wherein,

the surface layer conductor contains at least a metal selected from a group comprising gold, silver, and copper.

As described above, in the circuit substrate according to the present embodiment, the surface layer conductor contains at least a metal selected from a group comprising gold, silver, and copper. Accordingly, in the circuit substrate according to the present embodiment, the resistance loss in the large current module using the substrate can be reduced, since the electric resistance of the surface layer conductor is low. Needless to say, it is preferable that the wiring resistance be lowered by having at least a portion, through which a large current is designed to flow, within the conductor patterns constituting the another surface layer conductor, the inner conductor, the via conductor, or the like, contain such a low resistance conductor (e.g., at least a metal selected from a group comprising gold, silver, and copper), when the circuit substrate comprises those conductors in addition to the surface layer conductor provided in the first principal region.

Meanwhile, the low resistance conductor such as gold, silver, copper, and an alloy containing those metals, that is used for the purpose of lowering the wiring resistance as described above has a relatively low melting point as compared with the other metals. When a sheet (dielectric layer) of a dielectric material, in which a conductor pattern containing such a metal having the relatively low melting point is buried, is fired at a temperature equal to or higher than the melting point of the metal, the metal is melted so that it may become difficult to maintain a desired shape of the conductor pattern. Therefore, when such a low resistance conductor is used as a conductor forming the surface layer conductor (and, depending on the configuration, the another surface layer conductor, the inner conductor, the via conductor, or the like, as described above), it is preferable to use, in the dielectric layer, ceramics that can be fired at a temperature lower than the melting point of the used low resistance conductor.

It should be noted that, it is preferable to use a so-called “Low Temperature Co-fired Ceramics (LTCC)” as the ceramics that can be fired at the temperature lower than the melting point of the used low resistance conductor. The use of the LTCC allows the low resistance conductor such as gold, silver, copper, and an alloy containing those metals to be used as the above described conductor. By means of this, in the circuit substrate according to the present embodiment comprising the surface layer conductor (and, depending on the configuration, the another surface layer conductor, the inner conductor, the via conductor, or the like, as described above) which contains any of those low resistance conductor, not only the resistance loss in the large current module using the substrate can be lowered by suppressing the wiring resistance, but also the problem of being difficult to maintain the desired shape of the conductor pattern due to the melt of the metal when the sheet (dielectric layer) of the dielectric material in which the conductor pattern containing such a metal having the relatively low melting point is buried is fired can be avoided.

Specifically, an eighth embodiment of the present invention is a circuit substrate including the features of the seventh embodiment of the present invention, wherein,

the surface layer conductor contains copper; and

the ceramics is ceramics which can be sintered at a temperature lower than 1080° C.

Also, a ninth embodiment of the present invention is a circuit substrate including the features of the seventh embodiment of the present invention, wherein,

the surface layer conductor contains silver; and

the ceramics is ceramics which can be sintered at a temperature lower than 960° C.

As described above, an example of the ceramics constituting the base of the circuit substrate according to the above two embodiments is the LTCC. Examples of such a LTCC may be made from a mixture of a glass powder, and an inorganic powder such as an alumina powder, an aluminum nitride powder, a silica powder, and a mullite powder; an inorganic composition containing as a main component, for example, BaO, Al₂O₃, and SiO₂; or the like.

Examples of the raw materials for the above described ceramics made from the mixture of the glass powder and the inorganic powder are borosilicate glass having B₂O₃—SiO₂ as a main component; the borosilicate glass containing alkaline-earth metal oxide such as Cao and MgO and/or alkali metal oxide, as a main component, and ZnO and/or ZrO₂ etc. as a sub component; glass containing SiO₂ and alkali metal oxide as main components, and ZnO and/or ZrO₂ etc. as a sub component similarly to the above. For example, as the above described glass, crystallized glass of diopside series, cordierite series, spodumene series, or the like, may be used. Since the crystallized glass can attain a high strength by being crystallized, the glass powder may be used solely.

As described above, in the circuit substrates according to the above two embodiments, the low resistance conductor is selected as the conductor forming the surface layer conductor (and, depending on the configuration, the another surface layer conductor, the inner conductor, the via conductor, or the like, as described above), and the ceramics that can be fired at the temperature lower than the melting point of that low resistance conductor is used. Therefore, in the circuit substrate according to those embodiments, the resistance loss in the module including this substrate can be reduced since the wiring resistance can be lowered.

Further, in the circuit substrates according to those embodiments, since the ceramics constituting the base of the substrate can be fired at the temperature lower than the melting point of the low resistance conductor, the problem of being difficult to maintain the desired shape of the conductor pattern due to the melt of the metal when the base formed of the dielectric layer containing the ceramics is fired can be avoided.

Hereinafter, there will be described structures, properties, or the like of circuit substrates according to various embodiments of the present invention. Note, however, the descriptions below are merely for the purpose of exemplifying, and thus, those should not be construed as limitations on the scope of the present invention.

### EXAMPLES

### (1) Preparation of Evaluation Sample Substrate

In any of the evaluation samples, the surface layer conductor was configured to be exposed such that the surface of the surface layer conductor and the first principal surface were flush with each other, and the conductor was not projected from the first principal surface. In addition, a mixture of alumina and glass was used as the ceramics which became the dielectric layer (the base), and a conductor paste containing copper was used for forming the conductor pattern which became the surface layer conductor. The compact, in which the conductor pattern which became the surface layer conductor was buried in the sheet of the dielectric material, was formed by the above described “gel casting method.” The thus obtained compact was degreased by keeping the compact at 780° C. for 20 hours, and was fired by keeping the degreased compact at 960° C. for 5 hours.

A plurality of the sample substrates, each having the inverted trapezoid cross sectional shape of the surface layer conductor, cut by the plane perpendicular to the first principal surface, were prepared as an example 1 group; a plurality of the sample substrates, each having the cross sectional shape which is the inverted step-like shape, were prepared as an example 2 group; a plurality of the sample substrates, each having the cross sectional shape which is the inverted step-like shape wherein the corners of the steps were rounded (blurred), were prepared as an example 3 group; and a plurality of the sample substrates, each having the cross sectional shape which is a rectangular, were prepared as a comparative example 1 group. In each of the sample groups, a plurality of the sample substrates were made, the substrates having the surface layer conductors with various thicknesses, a variety of the numbers of steps (for the surface layer conductor having the inverted step-like cross sectional shape), a variety of degrees of widening in the cross section of the surface layer conductor from the side E2 to the side E1, or the like. Each of the sample groups will be described below in detail.

Firstly, as the sample group according to the example 1, a plurality of the sample substrates were prepared, each in which the cross sectional shape of surface layer conductor, cut by the plane perpendicular to the first principal surface, is the inverted trapezoid, as described above. The surface layer conductor having such a cross sectional shape was formed using a metal mask having an opening whose shape of a cross section, cut by the plane perpendicular to a principal surface, was formed to be a trapezoid, when forming the conductor pattern to become the surface layer conductor. The thickness of the surface layer conductor was varied within a range, which is preferable in the present invention, from 60 μm or more to 300 μm or less. A difference between the length L1 of the side E1 and the length L2 of the side E2 was varied within a range, which is preferable in one of the embodiments of the present invention, from 10 μm or more to 300 μm or less.

As the sample group according to the example 2, a plurality of the sample substrates were prepared, each in which the cross sectional shape of surface layer conductor, cut by the plane perpendicular to the first principal surface, is the inverted step-like shape, as described above. The surface layer conductor having such a cross sectional shape was formed by printing the conductor paste a plurality of times using the screen printing method such that the width of the conductor pattern to become the surface layer conductor became wider as it came closer to the first principal surface when forming the conductor pattern to become the surface layer conductor. The thickness of the surface layer conductor was varied within a range, which is preferable in the present invention, from 60 μm or more to 300 μm or less.

As the sample group according to the example 3, a plurality of the sample substrates were prepared, each in which the cross sectional shape of surface layer conductor, cut by the plane perpendicular to the first principal surface, is the inverted step-like shape in which the corners corresponding to the portions of the corners of the step are rounded (blurred), as described above. The surface layer conductor having such a cross sectional shape was formed by printing, a plurality of times, the conductor paste whose property (viscosity) was adjusted so as to be suitable for having the corners corresponding to the portions of the corners of the step being rounded, using the screen printing method such that the width of the conductor pattern to become the surface layer conductor became wider as it came closer to the first principal surface when forming the conductor pattern to become the surface layer conductor. The thickness of the surface layer conductor was varied within a range, which is preferable in the present invention, from 60 μm or more to 300 μm or less.

It should be noted that, in the sample groups according to the example 2 and example 3, each in which the cross sectional shape of surface layer conductor is the inverted step-like shape, the number of steps in the cross section having the inverted step-like shape was varied depending on the thickness of the surface layer conductor such that the thickness per one step in the cross section of the inverted step-like shape fell within the range, which is preferable in one of the embodiment of the present invention, from 40 μm or more to 100 μm or less. For example, the number of steps of the surface layer conductor in the cross section having the inverted step-like shape was set at two steps in the sample substrate having the surface layer conductor whose thickness is 120 μm, and the number of steps of the surface layer conductor in the cross section having the inverted step-like shape was set at three steps in the sample substrate having the surface layer conductor whose thickness is 200 μm or more.

Further, as described above, the preferable range for the difference between the sides on which two quadrangles next to each other contact with each other among a plurality of the quadrangles constituting the inverted step-like cross sectional shape is from 40 μm or more to 150 μm or less (20 μm or more to 75 μm or less at each of the both ends when the difference is evenly allocated to the both ends). Accordingly, in the sample substrates in which the number of steps of the surface layer conductor in the cross section having the inverted step-like shape was set at two, the difference between the length L1 of the side E1 and the length L2 of the side E2 was varied within a range from 40 μm or more to 150 μm or less. Similarly, in the sample substrates in which the number of steps of the surface layer conductor in the cross section having the inverted step-like shape was set at three, the difference between the length L1 of the side E1 and the length L2 of the side E2 was varied within a range from 80 μm or more to 300 μm or less.

On the other hand, as the sample group according to the comparative example 1, a plurality of the sample substrates were prepared, each in which the cross sectional shape of surface layer conductor, cut by the plane perpendicular to the first principal surface, is the rectangular, as described above. The surface layer conductor having such a cross sectional shape was formed using a metal mask having an opening whose shape of a cross section, cut by the plane perpendicular to a principal surface, was formed to be rectangular, when forming the conductor pattern to become the surface layer conductor. The thickness of the surface layer conductor was varied within a range from 60 μm or more to 300 μm or less, similarly to the examples 1 and 2 described above.

### (2) Observation of the Evaluation Sample Substrate

The various thus prepared sample substrates, included in each of the sample groups according to each of the example 1, the example 2, the example 3, and the comparative example 1, were polished, and thereafter, they were observed using a light microscope as to existence or non-existence of a crack in the ceramics base around the cross section of the surface layer conductor, cut by the plane perpendicular to the first principal surface. In addition, after cycle tests (durability tests) having testing conditions listed below, similar observations were made using the light microscope as to existence or non-existence of the crack.

### (3) Cycle Test for the Evaluation Sample Substrate

As a test condition 1 corresponding to a typical durability test condition, each of the sample substrates was made to experience 1000 cycles (times) of temperature change from −50° C. to 150° C. As a test condition 2 corresponding to a more severe durability test condition, each of the sample substrates was made to experience 1000 cycles (times) of temperature change from −50° C. to 200° C. As a test condition 3 corresponding to a much more severe durability test condition, each of the sample substrates was made to experience 1000 cycles (times) of temperature change from −50° C. to 250° C.

### (4) Evaluation Result of the Evaluation Sample Substrate

Results of the observations for the various sample substrates included in each of the sample groups according to the example 1, the example 2, the example 3, and the comparative example 1, using the light microscope, are shown in a Table 1 below. The observations were carried out, immediately after the sample substrates were fired, and after each of the cycle tests using the test conditions 1 to 3.

TABLE 1

| | Immediately | | | |
|---|---|---|---|---|
| | after completion | | | |
| | (Immediately | After cycle test | | |
| | after fired) | Test condition 1 | Test condition 2 | Test condition 3 |
| Example 1 | No crack | No crack | No crack | No crack |
| | thickness: | thickness: | thickness: | thickness: |
| | 60-300 μm | 60-300 μm | 60-250 μm | 60-200 μm |
| | | | Crack | Crack |
| | | | thickness: | thickness: |
| | | | 300 μm | 250 μm or more |
| Example 2 | No crack | No crack | No crack | No crack |
| | thickness: | thickness: | thickness: | thickness: |
| | 60-300 μm | 60-300 μm | 60-300 μm | 60-250 μm |
| | | | | Crack |
| | | | | thickness: |
| | | | | 300 μm |
| Example 3 | No crack | No crack | No crack | No crack |
| | thickness: | thickness: | thickness: | thickness: |
| | 60-300 μm | 60-300 μm | 60-300 μm | 60-300 μm |
| Comparative | Crack | — | — | — |
| Example 1 | already found | | | |
| | even when | | | |
| | thickness is | | | |
| | 60 μm | | | |

As clear from the results shown in the Table 1, in the sample group according to the comparative example 1 (substrates corresponding to the prior art, each having the surface layer conductor whose shape of the cross section, cut by the plane perpendicular to the first principal surface, is rectangular), the crack was already found around the surface layer conductor in the sample substrate having the thinnest thickness (60 μm), at a point in time immediately after firing and even before the cycle tests. It is therefore obvious that the crack will be found around the surface layer conductor in the microscope observations after the cycle tests, since the microscope observations after the cycle tests are more severe evaluations. Further, it is also obvious that the crack will be found around the surface layer conductor in the sample substrates having the thicker surface conductor layers within the comparative example 1.

In contrast, in the sample group according to the example 1, corresponding to the embodiment of the present invention (substrates, each having the surface layer conductor whose shape of the cross section, cut by the plane perpendicular to the first principal surface, is the inverted trapezoid), no occurrence of the crack was found in the microscope observation after the cycle test using the test condition 1 which corresponds to the typical durability test condition. However, in the microscope observations after the cycle tests using the test condition 2 corresponding to the more severe durability test condition, and using the condition 3 corresponding to the much more severe durability test condition, the occurrences of the crack were found in the sample substrates having the thick surface layer conductor (250 μm or more, and 300 μm, respectively).

Further, in the sample group according to the example 2, corresponding to the embodiment of the present invention (substrates, each having the surface layer conductor whose shape of the cross section, cut by the plane perpendicular to the first principal surface, is the inverted step-like shape), no occurrence of the crack was found in the microscope observations after the cycle test using the test condition 1 corresponding to the typical durability test condition, and after the cycle test using the test condition 2 corresponding to the more severe durability test condition. However, in the microscope observation after the cycle test using the test condition 3 corresponding to the much more severe durability test condition, the occurrence of the crack was found in the sample substrates having the thickest surface layer conductor (300 μm).

Furthermore, in the sample group according to the example 3, corresponding to the embodiment of the present invention (substrates, in which the cross sectional shape of surface layer conductor, cut by the plane perpendicular to the first principal surface, is the inverted step-like shape in which the corners corresponding to the portions of the corners of the step are rounded (blurred)), no occurrence of the crack was found in the microscope observations after any of the cycle tests using the any of the durability test conditions (that is, the conditions 1 to 3) including the test condition 3 corresponding to the severe durability test condition.

From the results described above, it is confirmed that the crack caused by the change in the substrate temperature can be effectively suppressed in the ceramics substrate having the surface region in which the surface layer conductor having the sufficient thickness for the flow of the large current is buried, by designing the shape of the cross section of the part of the surface layer conductor, the part being buried in the base, cut by the plane perpendicular to the surface of the substrate such that the end portion at the surface side is wider than the end portion at the side opposite to the surface side.

Although some embodiments with certain configurations and the corresponding examples have been described for the purpose of explanation of the present invention, it is needless to say that the scope of the present invention is not limited to those exemplary embodiments and examples. The scope of the present invention should be construed as including modifications that can be properly added within the scope of the description in the claims and specification.

1. A circuit substrate comprising a base which includes at least one dielectric layer mainly containing ceramics, and at least one surface layer conductor formed at a first principal surface which is one of two principal surfaces,
wherein,
a part of said surface layer conductor is exposed from said base at said first principal surface, and the rest part of said surface layer conductor is buried in said base;
at least a portion of said surface layer conductor has a thickness of 60 μm or more in a direction perpendicular to said first principal surface;
a shape of a cross section of said part of said surface layer conductor, said part being buried in said base, cut by a particular plane perpendicular to said first principal surface, includes a side E1 which is a line of intersection of said cross section and said first principal surface, and a side E2 parallel to said side E1;
a length L1 of said side E1 is longer than a length L2 of said side E2; and
both ends of said side E2 are positioned between both ends of said side E1 in a projective plane parallel to said first principal surface.

2. The circuit substrate according to claim 1, wherein,
a difference between said length L1 and said length L2 is equal to or longer than 10 μm and equal to or shorter than 300 μm.

3. The circuit substrate according to claim 1, wherein,
said shape of said cross section is an inverted trapezoid having said side E1 and said E2 as an upper side and a lower side, respectively.

4. The circuit substrate according to claim 1, wherein,
said shape of said cross section is an inverted step-like shape obtained by layering a plurality of quadrangles including at least a quadrangle having said side E1 as one of four sides, and a quadrangle having said side E2 as one of four sides; and
in an plane which includes a plane at which two of said quadrangles next to each other among a plurality of said quadrangles constituting said inverted step-like shape contact with each other, both ends of a side of said quadrangle closer to said side E2 are positioned between both ends of a side of said quadrangle closer to said side E1.

5. The circuit substrate according to claim 4, wherein,
at least one of a plurality of corners, corresponding to two corners closer to said side E2 among four corners which each of a plurality of said quadrangles constituting said inverted step-like shape has, is rounded.

6. The circuit substrate according to claim 4, wherein,
a thickness of each of said quadrangles forming said inverted step-like shape is equal to or longer than 40 μm and equal to or shorter than 100 μm; and
in said plane which includes said plane at which two of said quadrangles next to each other among a plurality of said quadrangles constituting said inverted step-like shape contact with each other, a difference between a length of said quadrangle closer to said side E2 and a length of said quadrangle closer to said side E1 is equal to or longer than 40 μm and equal to or shorter than 150 μm.

7. The circuit substrate according to claim 1, wherein,
said surface layer conductor includes at least one metal selected from a group consisting of gold, silver, and copper.

8. The circuit substrate according to claim 7, wherein,
said surface layer conductor includes copper; and
said ceramics is ceramics which can be sintered at a temperature lower than 1080° C.

9. The circuit substrate according to claim 7, wherein,
said surface layer conductor includes silver; and
said ceramics is ceramics which can be sintered at a temperature lower than 960° C.
